(19) United States
(12) Patent Application Publication
(10) Pub. No.: US 2012/0000508 A1
(43) Pub. Date: Jan. 5, 2012

(54) THERMAL DEVICE AND PHOTOVOLTAIC MODULE HAVING THE SAME

(75) Inventor: Chui-Ling YIP, Hong Kong (HK)

(73) Assignee: Du Pont Apollo Limited, Hong Kong (HK)

(21) Appl. No.: 13/171,428

(22) Filed: Jun. 28, 2011

Related U.S. Application Data
(60) Provisional application No. 61/360,928, filed on Jul. 2, 2010.

(51) Int. Cl. H01L 31/052; H05K 7/20

(52) U.S. Cl. 136/246; 165/104.33

(57) ABSTRACT

Disclosed herein are a thermal device and a photovoltaic module having the same. The photovoltaic module includes a photovoltaic device, a thermal device, and an adhesive layer. The photovoltaic device includes a front substrate, a back substrate and a photovoltaic cell disposed between the two substrates. The thermal device is disposed adjacent to the back substrate for dissipating heat away from the photovoltaic device, and includes a chassis, several pipes and a thermal carrier. The chassis having several depressed channels is disposed adjacent to the back substrate. The pipes are disposed in the depressed channels and a coolant runs through the pipes to take away heat. The thermal carrier is used to fill the depressed channels and fully covers the pipes. The adhesive layer is disposed on the chassis for adhering the chassis and the back substrate.

### RELATED APPLICATIONS

This application claims priority to U.S. Provisional Application Ser. No. 61/360,928, filed Jul. 2, 2010, which is herein incorporated by reference.

### BACKGROUND

1. Technical Field

The present disclosure relates to an energy conversion module. More particularly, the present disclosure relates to a thermal device and a photovoltaic module having the same.

2. Description of Related Art

In the trend of green technology, solar energy has gained numerous research attentions for being a seemingly inexhaustible energy source. For such purpose, photovoltaic (PV) devices that convert light energy, particularly sunlight, into electrical energy are developed. During the energy conversion process, no greenhouse gas is produced. Further, the electrical energy generated by the PV devices can be used for all kinds of applications as those achieved by batteries or existing power generators. For such reasons, the PV devices are getting more and more popular in the market, and are now widely used in various electronic products.

A known PV device typically includes a PV cell for converting solar energy, two parallel substrates for protecting the PV cell, a sealant for sealing the internal space of the PV device, an electric ribbon and a junction box for transmitting electric current generated by the PV cell. Normally, the PV device is exposed to the sun to receive sunlight and subsequently converts the received light to electricity. Upon being exposed to the sunlight for a period of time, the PV device would be heated with its temperature rises dramatically. The heat accumulated in the PV device would affect the performance of the PV device, and in a worse situation, damage the PV device. For instance, the sealing material is degraded, and thereby deteriorating the tightness of the sealing, and inevitably overheat the PV cell to a level that would significantly decrease photon-to-electricity (PE) efficiency. These defects may ultimately lead to the complete breakdown of the PV device.

### SUMMARY

In view of the above, a thermal device and a photovoltaic module having the same are provided to solve the problems of thermal damage of photovoltaic devices.

According to one aspect of the disclosure, a photovoltaic module is provided. The photovoltaic module includes a photovoltaic device, a thermal device, and an adhesive layer. The photovoltaic device includes a front substrate, a back substrate, and a photovoltaic cell disposed between the two substrates. The thermal device disposed adjacent to the back substrate for dissipating heat away from the photovoltaic device includes a chassis, several pipes, and a thermal carrier. The chassis has several depressed channels. The pipes are disposed in the depressed channels, and a coolant runs through the pipes to take away heat. The thermal carrier is filled in the depressed channels and fully covers the pipes. The adhesive layer is disposed between the back substrate and the chassis to adhere the photovoltaic device and the thermal device.

In one embodiment, the adhesive layer is patterned to avoid overlaying the thermal carrier such that the thermal carrier is in direct contact with the back substrate.

In another embodiment, the adhesive layer is made of silicone, butyl resin, or polyisobutylene resin, and the thermal carrier is any of the thermal carrier is any of a paint of CRISTOL-TPP®, a Celvaseal® Leak Sealant, a 891-7 Dow Coming® Vacuum Grease, or a potting glue of ShinEtsu® KE200.

In a further embodiment, the photovoltaic device further includes a junction box disposed on the back substrate. The chassis has an opening to expose the junction box.

In yet another embodiment, the thermal device further includes a first conveying tube and a second conveying tube that are disposed outside the chassis and are not covered by the photovoltaic device. The first conveying tube is connected to the pipes to convey the coolant into the pipes. The second conveying tube is connected to the pipes to convey the coolant away from the pipes.

In yet a further embodiment, the photovoltaic module further includes at least one C-clamp disposed at the edge of the photovoltaic device and the thermal device to fix the two devices.

According to another aspect of the disclosure, a thermal device for dissipating heat away from a photovoltaic device is provided. The thermal device includes a chassis, several pipes, a thermal carrier, and an adhesive layer. The chassis having several depressed channels is disposed adjacent to a back substrate of the photovoltaic device. The pipes are disposed in the depressed channels and a coolant runs through the pipes to take away heat. The thermal carrier is used to fill the depressed channels and fully covers the pipes. The adhesive layer is disposed on the chassis for adhering the chassis and the back substrate.

In the foregoing, the photovoltaic device and the thermal device are adhered together by the adhesive layer, without forming any air gap between the two devices. The heat from the photovoltaic device can therefore be effectively transferred to the thermal device. Further, for the reason that the pipes are fully covered by the thermal carrier and the thermal carrier is in direct contact with the back substrate, the thermal conductivity of the thermal device is improved.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is an exploded diagram of a photovoltaic module according to one embodiment of the disclosure;

FIG. 2 is a cross-sectional view if the photovoltaic module in FIG. 1 taken along line 4-4′; and

FIG. 3 is a photovoltaic module according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. A photovoltaic module including a photovoltaic device and a thermal device for dissipating heat away from the photovoltaic is provided.

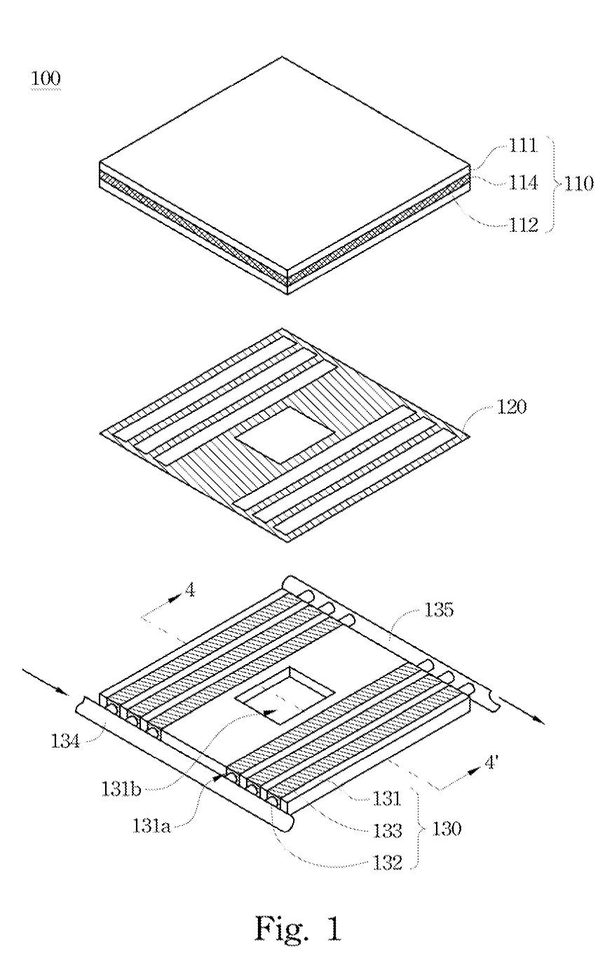

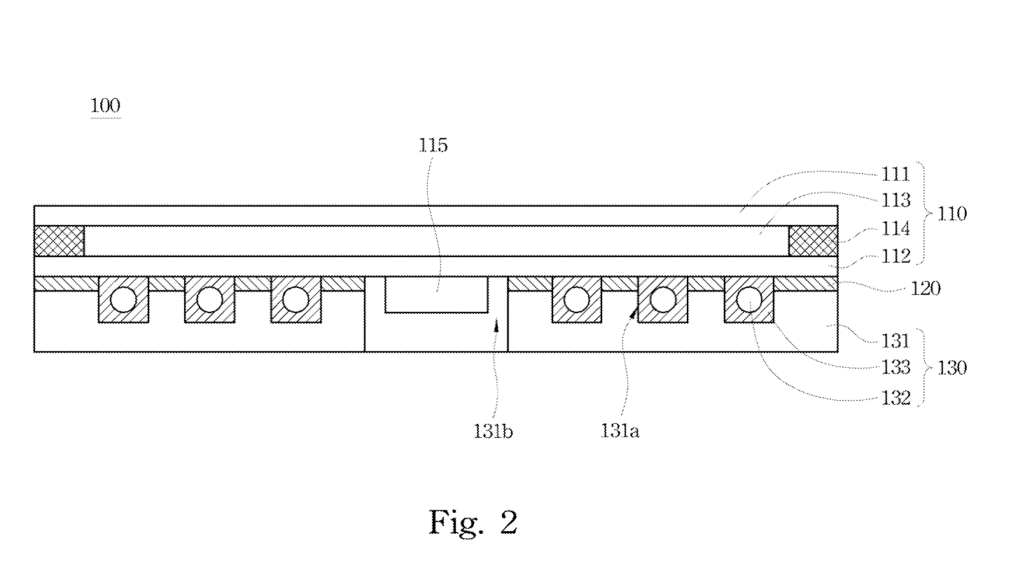

FIG. 1 is an exploded diagram of a photovoltaic module according to one embodiment of the disclosure. FIG. 2 is a cross-sectional view of the photovoltaic module in FIG. 1 taken along line 4-4′. The photovoltaic module 100 includes a photovoltaic device 110 for converting energy, a thermal device 130 for dissipating heat away from the photovoltaic device 110, and an adhesive layer 120 for joining the two devices 110 and 130.

The photovoltaic device 110 includes a front substrate 111, a back substrate 112, and a photovoltaic cell 113 (not shown in FIG. 1) disposed between the two substrates 111 and 112. Each of the front substrate 111 and the back substrate 112 is a glass substrate, a polymeric sheet, or any other suitable substrate materials. For example, each of the substrates 111 and 112 may be a transparent conductive oxide (TCO) coated glass, a polytetrafluoroethylene (PTFE) film (such as the DuPont™ Teflon® film), a polyethylene naphthalate (PEN) film (such as the DuPont™ Teonex® polyethylene naphthalate film), or a polyester film (such as the DuPont™ Melinex® ST polyester film). Within the scope of the present disclosure, the photovoltaic cell 113 is meant to include any articles that can convert light into electricity. Generally, photovoltaic cells may be categorized into crystalline photovoltaic cells and thin-film photovoltaic cells.

The photovoltaic material used in crystalline photovoltaic cells may be mono-crystalline silicon, poly-crystalline silicon or micro-crystalline silicon. The thin-film photovoltaic cells may be produced by depositing one or more thin layers of photovoltaic material on a substrate. Many different photovoltaic materials are deposited by use of various deposition methods on a variety of substrates. Thin-film photovoltaic cells are usually categorized according to the photovoltaic material used therein, which includes, but is not limited to, amorphous silicon (a-Si) and other thin film silicon, copper indium selenide (CIS), cadmium telluride (CdTe), dye sensitized photovoltaic materials, and other organic photovoltaic materials.

Practically, the photovoltaic cell 113 between the two substrates 111 and 112 is surrounded by a sealant 114. The sealant 114 is disposed along the peripheral area between the front substrate 111 and the back substrate 112 such that an enclosed space is formed among the sealant 114 and the two substrates 111 and 112. The photovoltaic cell 113 is situated in the enclosed space so that it is protected from oxidation and corrosion. The material of the sealant 114 can be selected in accordance with practical product needs, and is not limited in the disclosure. For example, the sealant 114 may be made of polyisobutylene (NB), butyl rubber, VAMAC®, ethylene acrylic elastomers, Hypalon®, or chlorosulfonated polyethylene. The above mentioned materials are for exemplifications only, and are not intended to limit the scope of the disclosure. Moreover, the photovoltaic cell 113 is further surrounded by an encapsulant sheet, such as EVA. Practically, the encapsulant sheet is disposed between the photovoltaic cell 113 and the back substrate 112.

Although the photovoltaic device 110 is exemplified by including the two substrates 111, 112, the photovoltaic cell 113, and the sealant 114 in the disclosure, the composition of the photovoltaic device 110 is not limited thereto. For example, the photovoltaic device 110 may further include a junction box for manipulating electric signals, an electric ribbon for transmitting electric current, and/or other components.

The description of the disclosure now directs to the thermal device 130 of the photovoltaic module 100. The thermal device 130 is adhered to the back substrate 112 of the photovoltaic device 110 by the adhesive layer 120 and is used for dissipating heat away from the photovoltaic device 110. The thermal device 130 includes a chassis 131, several pipes 132 and a thermal carrier 133. The chassis 131, whose material is exemplified by aluminum in the embodiment, has several depressed channels 131a that are parallel to each other. The pipes 132, such as thermal conductive metal pipes, are disposed in the depressed channels 131a in parallel. A coolant, such as water, runs through the pipes 132 to take away heat. The thermal carrier 133 that is made of a thermal conductive material is used to fill the depressed channels 131a and fully covers the pipes 132. Practically applicable materials of the thermal carrier 133 include a paint Ouch as CRISTOL-TPP® made by Krishna), a sealant (such as Celvaseal® Leak Sealant), a grease (such as 891-7 Dow Corning® Vacuum Grease), or a potting glue (such as ShinEtsu® KE200) for example.

As depicted in FIG. 1, the adhesive layer 120 is patterned to avoid overlaying the thermal carrier 133; in other words, the thermal carrier 133 is not covered by the adhesive layer 120, so that the thermal carrier 133 is in direct contact with the back substrate 112. In the present embodiment, because the pipes 132 are fully covered by the thermal carrier 133 and the thermal carrier 133 is in direct contact with the back substrate 112, the heat of the photovoltaic device 110 can be transferred to the coolant through the chassis 131, the thermal carrier 133 and the pipes 132. In this manner, the heat can be taken away from the photovoltaic device 110 effectively, and thus the operation stability and the energy conversion efficiency of the photovoltaic device 110 are enhanced.

In the present embodiment, the thermal device 130 and the photovoltaic device 110 are adhered to each other by the adhesive layer 120. The examples of the material of the adhesive layer 120 include silicone, butyl resin, and polyisobutylene. However, the adhesive layer 120 is not limited to the above-mentioned materials. Any other suitable materials known to a person skilled in the art may be used in the photovoltaic module 100 of the present embodiment.

The thermal device 130 of the present embodiment is further elaborated below with reference to FIG. 1 and FIG. 2. The thermal device 130 of the present embodiment further includes a first conveying tube 134 and a second conveying tube 135 that are respectively connected to the pipes 132. The first conveying tube 134 conveys the coolant into the pipes 132, and the second conveying tube 135 conveys the coolant away from the pipes 132. As depicted in FIG. 1, the two conveying tubes 134 and 135 are disposed outside the chassis 131 and are not covered by the photovoltaic device 110. Each conveying tube 134 or 135 includes an anticorrosion coating formed on the outer surface of the conveying tube 134 or 135 to increase the weatherability of the conveying tube 134 or 135. Due to the external disposition of the two conveying tubes 134 and 135, the area of the pipes 132 that is in contact with the photovoltaic device 110 can be maximized, which increases the heat transferring efficiency of the thermal device 130.

More specifically, the two conveying tubes 134 and 135 are respectively situated on two opposite sides of the chassis 131. The first conveying tube 134 is connected to one end of each parallel pipes 132, and the second conveying tube 135 is connected to the other end of each pipes 132. The relatively-low-temperature coolant enters the pipes 132 from the first conveying tube 134 to undergo the heat exchange. Afterwards, the heat-exchanged, relatively-high-temperature coolant leaves the pipes 132 and is conveyed away from the thermal device 130 through the second conveying tube 135. The heat that is carried by the coolant can be collected for further use. In other words, the photovoltaic module 100 of the present embodiment provides thermal energy (from the thermal device 130) in addition to electricity (from the photovoltaic device 110), and thus the total energy yield of the photovoltaic module 100 is increased.

The chassis 131 of the thermal device 130 further includes an opening 131b that is configured to correspond with the location of a junction box 115 of the photovoltaic device 110. The junction box 115 is disposed on the back substrate 112 and is exposed from the opening 131b. As such, the junction box 115 is not covered by the chassis 131 and therefore can be adequately ventilated. For such reason, the problems caused by overheating the junction box 115 are prevented, and the maintenance of the junction box 115 can be easily carried out through the opening 131b.

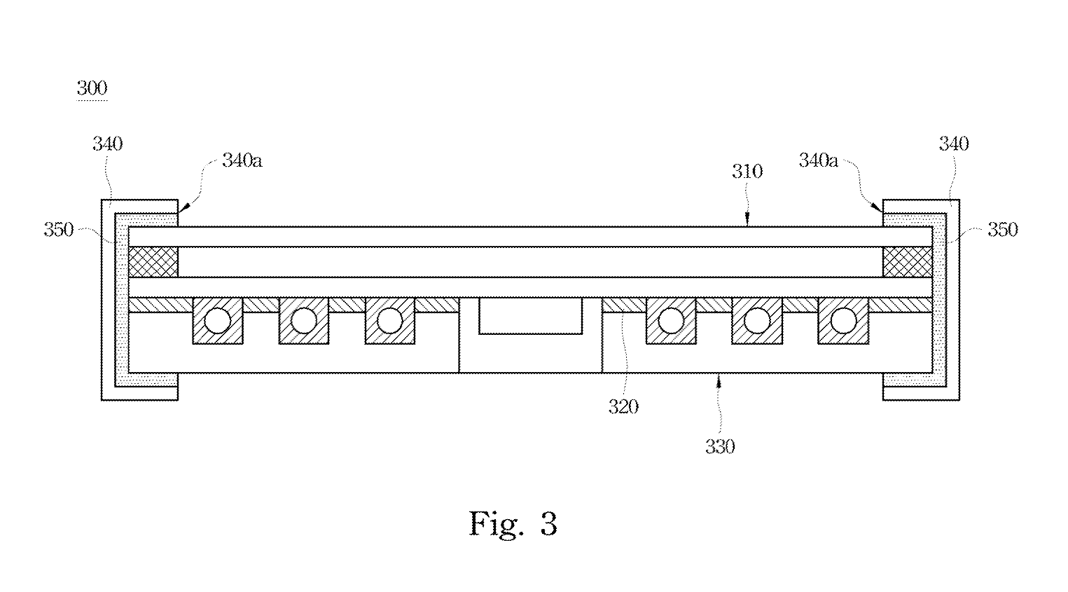

FIG. 3 is a photovoltaic module according to another embodiment of the disclosure. In addition to the photovoltaic device 310, the thermal device 330 and the adhesive layer 320, the photovoltaic module 300 further includes at least one C-clamp 340. The photovoltaic device 310, the thermal device 330 and the adhesive layer 320 are configured similarly as that of the photovoltaic module 100 in FIG. 1 and FIG. 2, and will not be repeated here. The at least one C-clamp 340 is disposed at the edge of the photovoltaic device 310 and the thermal device 330 to fix the two devices 310 and 330. In the present embodiment, the photovoltaic module 300 includes a pair of the C-clamps 340 that are disposed on two opposite sides of the photovoltaic device 310 and the thermal device 330. In order not to interfere with the first conveying tube and the second conveying tube (not shown in FIG. 3), the two opposite sides for disposing the C-clamps 340 are different from the sides for disposing the conveying tubes.

Moreover, in the present embodiment, the photovoltaic module 300 further includes a sealing material 350. Each C-clamp 340 includes an accommodating room 340a for accommodating a portion of the photovoltaic device 310 and a portion of the thermal device 330. The sealing material 350 is disposed in each accommodating room 340a to form a tight sealing between the two devices 310 and 330 and the C-clamps 340. The at least one C-clamp 340 not only helps the fixture of the two devices 310 and 330, but facilitates the water resistivity of the photovoltaic module 300 as well.

In the above-described thermal device and photovoltaic module having the same, the two devices are adhered to each other by a single adhesive layer, and the pipes, the chassis and the thermal carrier are packed closely and firmly. In this manner, the module eliminates any air gaps among components, so that the thermal conductivity is increased and a thin, compact photovoltaic module is realized accordingly. On the other hand, the photovoltaic module outputs both electricity and thermal energy, which increases the total yield and the efficiency of the module.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A photovoltaic module, comprising:
a photovoltaic device comprising a front substrate, a back substrate, and a photovoltaic cell disposed between the two substrates;
a thermal device disposed adjacent to the back substrate for dissipating heat away from the photovoltaic device, the thermal device comprising:
a chassis having a plurality of depressed channels;
a plurality of pipes disposed in the depressed channels, wherein a coolant runs through the pipes to take away heat; and
a thermal carrier filled in the depressed channels and fully covering the pipes; and
an adhesive layer disposed between the back substrate and the chassis to adhere the photovoltaic device and the thermal device.

2. The photovoltaic module of claim 1, wherein the adhesive layer is patterned to avoid overlaying the thermal carrier, such that the thermal carrier is in direct contact with the back substrate.

3. The photovoltaic module of claim 1, wherein the adhesive layer is made of silicone, butyl resin, or polyisobutylene.

4. The photovoltaic module of claim 1, wherein the photovoltaic device further comprises a junction box disposed on the back substrate, and the chassis further has an opening to expose the junction box.

5. The photovoltaic module of claim 1, wherein the thermal device further comprises:
a first conveying tube connected to the pipes to convey the coolant into the pipes; and
a second conveying tube connected to the pipes to convey the coolant away from the pipes, wherein the two conveying tubes are disposed outside the chassis and are not covered by the photovoltaic device.

6. The photovoltaic module of claim 5, wherein each conveying tube comprises an anticorrosion coating formed on the outer surface of the conveying tube to increase the weatherability of the conveying tube.

7. The photovoltaic module of claim 5, wherein the two conveying tubes are respectively situated on two opposite sides of the chassis.

8. The photovoltaic module of claim 1, further comprising a mounting bracket disposed at the edge of the photovoltaic device and the thermal device to fix the two devices.

9. The photovoltaic module of claim 8, wherein the mounting bracket comprises at least one C-clamp disposed at the edge of the photovoltaic device and the thermal device to fix the two devices.

10. The photovoltaic module of claim 9, wherein when the photovoltaic module comprises a pair of the C-clamps, the C-clamps are disposed on two opposite sides of the photovoltaic device and the thermal device.

11. The photovoltaic module of claim 9, wherein the at least one C-clamp comprises an accommodating room for accommodating a portion of the photovoltaic device and a portion of the thermal device, and the photovoltaic module further comprises:
a sealing material disposed in the accommodating room to form a tight sealing between the two devices and the at least one C-clamp.

12. The photovoltaic module of claim 1, wherein each substrate is a glass substrate or a polymeric sheet.

13. The photovoltaic module of claim 1, wherein the chassis is made of aluminum.

14. A thermal device for dissipating heat away from a photovoltaic device, comprising:
a chassis having a plurality of depressed channels disposed adjacent to a back substrate of the photovoltaic device;
a plurality of pipes disposed in the depressed channels, wherein a coolant runs through the pipes to take away heat;
a thermal carrier filled in the depressed channels and fully covers the pipes; and
an adhesive layer disposed on the chassis for adhering the chassis and the back substrate.

15. The thermal device of claim 14, wherein the adhesive layer is patterned to avoid overlaying the thermal carrier, such that the thermal carrier is in direct contact with the back substrate.
